(19) United States
(12) Patent Application Publication
(10) Pub. No.: US 2026/0107743 A1
(43) Pub. Date: Apr. 16, 2026

(54) PEDESTAL WITH AXIALLY SYMMETRIC EDGE PURGE PLENUM

(71) Applicant: Lam Research Corporation, Fremont, CA (US)

(72) Inventors: Christopher Gage, Truckee, CA (US); Nitin Kadam, Dharward (IN)

(21) Appl. No.: 19/116,292

(22) PCT Filed: Sep. 26, 2023
(86) PCT No.: PCT/US2023/075165

§ 371 Date: Mar. 27, 2025

Related U.S. Application Data
(60) Provisional application No. 63/377,865, filed on Sep. 30, 2022.

(51) Int. Cl. H10P 72/78; H10P 72/00; H10P 72/76

(52) U.S. Cl. CPC H10P 72/78; H10P 72/0402; H10P 72/7612; H10P 72/7616

(57) ABSTRACT

This disclosure pertains to pedestal assemblies for supporting wafers in semiconductor manufacturing tools and chambers. Such pedestal assemblies may have an edge purge system that includes an axially symmetric first plenum volume that includes at 2024/073447 least a first radial sub-volume, a first axial sub-volume, and a second radial sub-volume. The first axial sub-volume may be fluidically interposed between the first radial sub-volume and the second radial sub-volume. An optional second plenum volume may be provided as well and may be used to fluidically connect a region of a wafer support that is part of the pedestal assembly with a vacuum port to allow the wafer support to provide vacuum clamping functionality.

WO

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools typically require the supply of different reactant gases to wafer processing spaces located within one or more semiconductor processing chambers. Semiconductor wafers processed in such chambers are typically supported on a pedestal, e.g., a platform that may have a chuck or other system for immobilizing the wafer in place on a wafer support surface thereof, during processing operations.

Discussed herein are various improvements to pedestals for use in some semiconductor processing systems.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a pedestal assembly. The pedestal assembly may include a wafer support with a bottom side and an opposing top side that is configured to support a wafer of diameter D during semiconductor processing operations such that the wafer is centered on a center axis of the pedestal assembly. The pedestal assembly may have a first plenum volume that is substantially axially symmetric about the center axis of the pedestal assembly. The first plenum volume may include a first axial sub-volume, a first radial sub-volume, and a second radial sub-volume. The first axial sub-volume may fluidically connect, and be fluidically interposed between, the first radial sub-volume and the second radial sub-volume. The first radial sub-volume and the second radial sub-volume may both extend radially inwards toward the center axis from the first axial sub-volume. The first radial sub-volume may also extend radially inward to a location outside of a cylindrical zone of diameter D centered on the center axis. The second radial sub-volume may, in contrast, extend radially inward to a location inside of the cylindrical zone of diameter D centered on the center axis. The second radial sub-volume may be further from the top side of the wafer support than the first radial sub-volume.

In some implementations, the apparatus may further include a purge inlet that is fluidically connected with the first plenum volume within the pedestal assembly. The first plenum volume may be configured such that when a gas is flowed into the pedestal assembly via the purge inlet, the gas flows radially outward, relative to the center axis, from the second radial sub-volume to the first axial sub-volume and then flows from the first axial sub-volume to the first radial sub-volume before exiting the pedestal assembly via the first radial sub-volume.

In some implementations, the second radial sub-volume may be free of obstructions about at least 320° of arc, in total, about the center axis.

In some implementations, the pedestal assembly may further include a ring structure having a circumferential wall portion and a flange portion extending radially inward from the circumferential wall portion to a nominally circular opening with a diameter larger than D. The pedestal may also include an understructure having an annular portion with an upper surface that faces towards, and is spaced apart from, the bottom side of the wafer support. In such an implementation, the first axial sub-volume may be radially interposed between the circumferential wall portion and an outermost surface of the wafer support, the first radial sub-volume may be interposed between the flange portion and the wafer support, and the second radial sub-volume may be interposed between the understructure and the wafer support.

In some such implementations, the understructure may include a plurality of bosses that extend from the upper surface of the understructure and contact the bottom side of the wafer support. In some further such implementations, the bosses may occupy less than 40° of arc about the center axis in total.

In some such implementations, each boss may have a corresponding lift pin hole therethrough, each boss may have a contact surface that contacts the wafer support, and the contact surface of each boss and a portion of the wafer support that contacts that boss at the contact surface thereof may both be flat.

In some implementations, the first plenum volume may further include a second axial sub-volume, the second radial sub-volume may be fluidically interposed between the first axial sub-volume and the second axial sub-volume, the understructure may further include a tubular portion that has an upper end that is proximate the annular portion, the tubular portion may support the annular portion, and the second axial sub-volume may be bounded, at least in part, by an interior surface of the tubular portion.

In some implementations, the apparatus may further include a first compliant seal element and a support collar. The first compliant seal element may be in a load path that includes the tubular portion and spans between the support collar and the annular portion of the understructure, and the first compliant seal element may exert a compressive load on the annular portion of the understructure, thereby pressing it into contact with the wafer support.

In some implementations, the first plenum volume may further include a second axial sub-volume, and the second radial sub-volume may be fluidically interposed between the first axial sub-volume and the second axial sub-volume.

In some implementations, the pedestal assembly may further include a second plenum volume, one or more vacuum outlets, and one or more vacuum ports. The second plenum volume may be fluidically isolated from the first plenum volume within the pedestal assembly, the one or more vacuum ports may lead from the bottom side of the wafer support to the top side of the wafer support, and the second plenum volume may fluidically connect, and may be fluidically interposed between, the one or more vacuum ports and the one or more vacuum outlets.

In some implementations, the apparatus may further include a tubular element that bounds, in part, the second plenum volume.

In some implementations, the apparatus may further include a stem. The stem may support the wafer support, the tubular element may encircle the stem, and the second plenum volume may be further bounded, at least in part, by the stem.

In some implementations, the apparatus may further include a first compliant seal element, a second compliant seal element, and a support collar. The first compliant seal element may be in a first load path that includes the tubular portion and spans between the support collar and the annular portion of the understructure, the second compliant seal element may be in a second load path that includes the tubular element and also spans between the support collar and the annular portion of the understructure, the first compliant seal element may exert a compressive load on the annular portion of the understructure, thereby pressing it into contact with the wafer support, and the second compliant seal element may be arranged to cause a compressive load to be exerted on the annular portion of the understructure, thereby also pressing it into contact with the wafer support.

In some implementations, the ring structure, the understructure, and the wafer support may all be made of ceramic materials.

In some implementations, the ring structure may be made of aluminum nitride and the understructure may be made of aluminum oxide.

In some implementations, the wafer support may further include a plurality of low-contact-area (LCA) features distributed across a portion of the top side of the wafer support, and each LCA feature may be a protrusion from a recessed portion of the top side of the wafer support.

In some implementations, the apparatus may further include a showerhead configured to direct one or more processing gases—when the one or more processing gases are flowed into the showerhead—towards the top side of the wafer support.

In some implementations, the apparatus may also further include a semiconductor processing chamber within which the wafer support is located.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a cross-sectional side view of an example pedestal assembly that embodies an axially symmetric purge gas plenum volume.

FIG. 2 is the same as FIG. 1 but with most of the callouts removed and the structural features shown in light grey; the various elements shown in black are various plenum volumes and sub-volumes.

FIG. 3 shows a detail view of a corresponding region of FIG. 1 in which a ring structure, as well as adjacent structures, can be seen.

FIG. 4 shows a perspective view of an example understructure in isolation.

FIGS. 5 and 6 depict detail views of portions of a support collar visible in FIG. 1.

FIG. 7 depicts the example pedestal assembly of FIG. 1 in an exploded view.

FIG. 8 depicts a cross-sectional view of the pedestal assembly of FIGS. 1 through 7 in the context of a semiconductor processing chamber.

FIG. 9 depicts a detail view of the circled portion of FIG. 8.

The above-described Figures are provided to facilitate understanding of the concepts discussed in this disclosure, and are intended to be illustrative of some implementations that fall within the scope of this disclosure, but are not intended to be limiting—implementations consistent with this disclosure and which are not depicted in the Figures are still considered to be within the scope of this disclosure.

### DETAILED DESCRIPTION

As noted previously, semiconductor processing tools or chambers typically use a pedestal to support a wafer during processing operations. Such pedestals may incorporate a variety of subsystems to facilitate processing operations, including, for example, electrodes that may be used to generate RF energy to spark plasmas within the chamber, heaters and cooling systems for thermal management of the wafer, lift pin mechanisms for raising and lowering the wafer from and onto the pedestal, and/or chucking systems for clamping the wafer in place during processing operations.

In some cases, reactants involved in a particular processing operation may flow into the space between the underside of a wafer being processed and the wafer support surface of the pedestal on which the wafer rests. This can occur even when there is no pressure differential between the chamber interior and the underside of the wafer that would draw such gases underneath the wafer. For example, molecules of such gases may simply diffuse into the space between the wafer and the wafer support surface—even when the wafer edge is resting on a continuous, unbroken portion of the wafer support surface. In systems in which the wafer is clamped to the pedestal using a vacuum chuck, e.g., by drawing a vacuum on the underside of the wafer such that the region between the wafer and the wafer support surface is at a lower pressure than the pressure in the processing chamber, the resulting pressure differential between the underside of the wafer and the chamber atmosphere may actually act to draw processing gases from the chamber underneath the wafer.

Processing gases that reach the underside of the wafer may cause undesired deposition or etching to occur on the wafer edge, e.g., on the underside of the wafer adjacent the edge, or on the wafer bevel (the outer edges of wafers typically have a rounded profile, referred to as the bevel, that avoids the presence of hard/sharp edges that may be vulnerable to damage or which may give rise to burrs). One technique for preventing or reducing the likelihood of processing gases reaching the underside of the wafer or wafer bevel is to provide a purge gas, e.g., nitrogen, helium, argon, etc. (a gas that is selected to be non-reactive with the process gases used) about the circumference of the wafer.

The present inventors determined that pedestal assemblies as discussed herein may be used to provide uniform edge purge of a wafer about the entire circumference of the wafer. For example, one may use a pedestal that has a ring of purge gas ports that encircle, and direct purge gas at, the wafer. However, due to the fact that the purge gas is introduced at discrete locations proximate the wafer, the purge gas will invariably exhibit a concentration that varies about the circumference of the wafer, resulting in a corresponding localized variation in the efficacy of the purge gas with respect to preventing unwanted exposure of the underside and bevel region of the wafer to process gases. This results in a corresponding circumferential variance in the degree to which process gases are able to affect the underside and/or bevel of the wafer.

To address this issue, the present inventors conceived of the pedestal assemblies discussed herein to allow purge gas to be delivered around the entire circumference of a wafer in a nearly completely uniform manner that avoids or mitigates the potential for circumferential variance of the amount of purge gas delivered. Such pedestal assemblies may be made with a generally axially symmetric first plenum volume that has at least a first radial sub-volume, a first axial sub-volume, and a second radial sub-volume. The first axial sub-volume may fluidically connect the first radial sub-volume with the second radial sub-volume. The first radial sub-volume and the second radial sub-volume may both extend radially inward from the first axial sub-volume, with a portion of a wafer support of the pedestal assembly interposed between the first radial sub-volume and the second radial sub-volume. Such an arrangement allows purge gas to be flowed through the first plenum volume, e.g., from the second radial sub-volume to the first axial sub-volume, and then from the first axial sub-volume to the first radial sub-volume, and then directed towards the edge of the wafer in an evenly distributed manner.

The first plenum volume may be kept generally free of any radial obstructions, e.g., features that may block flow of gas along a plane that is parallel to, and coincident with, a center axis of the pedestal assembly. To the extent that such radial obstructions may be necessary, however, their effect may be minimized, e.g., by limiting the proximity of such radial obstructions to the first axial sub-volume and/or by limiting the total angle of arc about the center axis of the pedestal assembly occupied by such obstructions. For example, in some implementations, three columns or bosses may extend through the second radial sub-volume to allow for lift pins of the pedestal assembly to be passed through the wafer support of the pedestal assembly. Such features may, however, be limited in size or number so as to reduce or minimize the disruptive effect that such features may have on gases flowing through the first plenum volume. For example, in some implementations, such features may occlude at most 20°, 30°, or 40° of arc.

By using a first plenum volume that include radial sub-volumes both above and below the wafer support, and connecting the radial sub-volumes with an axial sub-volume (all of which are substantially axially symmetric about the center axis of the pedestal assembly), the flow path of purge gas exiting the pedestal assembly may be kept axially symmetric over a significant fraction of its length, e.g., extending from the portion of the first radial sub-volume closest to the center axis through the first axial sub-volume and at least part, if not all, of the second radial sub-volume. Providing such a relatively long axially symmetric flow path allows for any circumferential variation in the concentration of the purge gas at the point where the purge gas is introduced into the first plenum volume to be evened out prior to exiting the first plenum volume—generally speaking, the longer such a flow path is, the less circumferential variation there will be in the purge gas delivery from the first plenum volume.

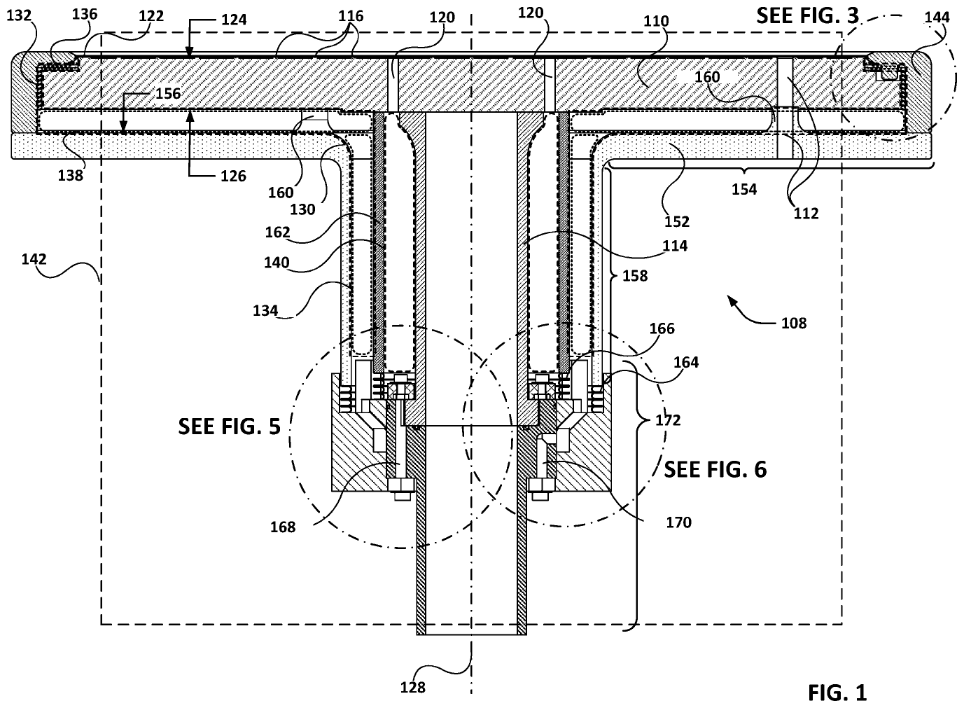

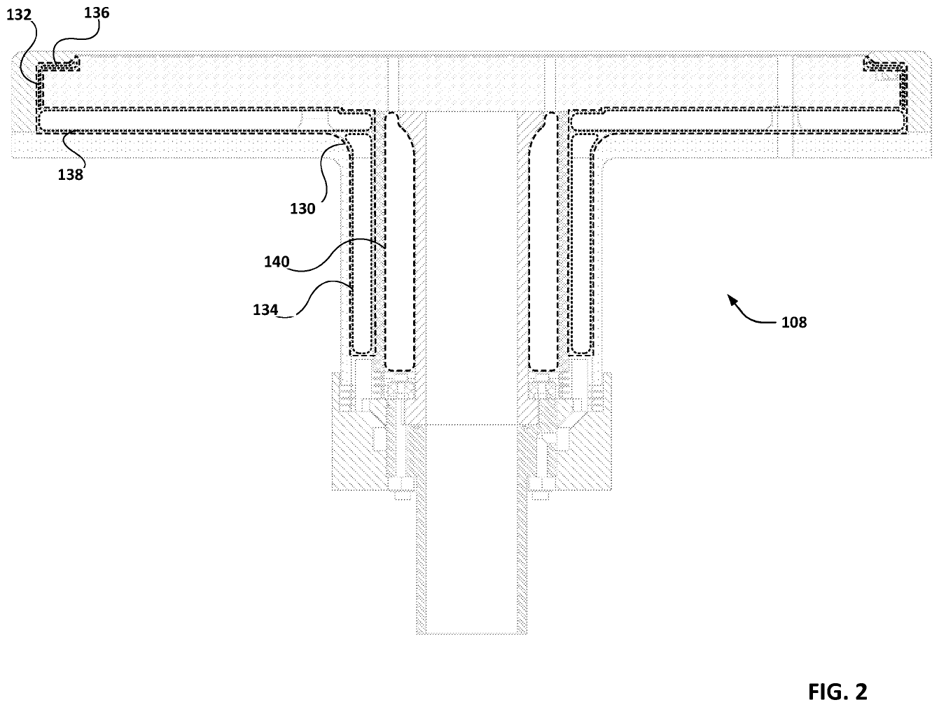

FIG. 1 depicts a cross-sectional side view of an example pedestal assembly that embodies an axially symmetric purge gas plenum volume. FIG. 2 is the same as FIG. 1 but with most of the callouts removed and the structural features shown in light grey; the various elements shown in black are various plenum volumes and sub-volumes. As shown in FIG. 1, a pedestal assembly 108 may include various structures that define a substantially axially symmetric first plenum volume 130 within the pedestal assembly. The first plenum volume 130 may include at least a first radial sub-volume 136, a first axial sub-volume 132, and a second radial sub-volume 138. The first radial sub-volume 136 may, for example, be partially bounded by a top side 124 of a wafer support 110 (opposite the bottom side 126 of the wafer support 110) and an underside of a flange portion of a ring structure 144 that encircles the wafer support 110. For example, the flange portion of the ring structure 144 may be offset vertically from the portion of the wafer support 110 positioned immediately below it, thereby forming a circumferential vertical gap between the wafer support 110 and the ring structure 144 within which the first radial sub-volume 136 is located. The ring structure 144 may have an opening in the middle that is, for example, nominally circular and has a diameter that is larger, e.g., on the order of a millimeter or a few millimeters, than a diameter D of the wafer that is to be processed using such a pedestal assembly 108.

Similarly, the second radial sub-volume 138 may, for example, be partially bounded by a bottom side 126 of the wafer support 110 and an upper surface of an understructure 152.

For example, the understructure 152 may generally be vertically offset from the bottom side 126 of the wafer support 110, thereby forming a vertical gap between the bottom side 126 and the understructure 152 within which the second radial sub-volume 138 is located.

The first axial sub-volume 132 may similarly be partially bounded by an inward-facing surface of a circumferential wall portion of the ring structure 144 that encircles the outermost surface of the wafer support 110. The first axial sub-volume 132 may also be partially bounded by an outward-facing surface of the wafer support 110. The first axial sub-volume may thus be located in a radial gap between the circumferential wall portion of the ring structure 144 and the outer perimeter of the wafer support 110.

The first radial sub-volume 136 may generally extend radially inward to a point that lies outside of a cylindrical zone 142, whereas the second radial sub-volume 138 may generally extend radially inward to a point that lies within the cylindrical zone 142. In some instances, the second radial sub-volume may be completely free of any obstacles in between its outermost edge and the cylindrical zone. In some such implementations, the cylindrical zone may have a radius that is less than 90%, less than 85%, less than 75%, less than 60%, less than 50%, or less than 40% of the distance from the center axis 128 to the outermost part of the wafer support 110.

The wafer support 110, in this example, is designed to function as a vacuum chuck. To that end, the wafer support 110 is equipped with vacuum ports 120, low-contact-area (LCA) features 116, and a seal ring 122. The seal ring 122 is a generally annular, raised portion of the top side 124 of the wafer support 110 that is machined, polished, lapped, etc., to provide a flat surface that is able to make contact with the edge region of a wafer placed thereupon so as to form a generally tight seal about the perimeter of the wafer. The LCA features 116 may, for example, be protrusions, bumps, mesas, or bosses in an otherwise recessed portion of the top side 124 of the wafer support 110 that are distributed in a generally even manner across the top side 124. The LCA features 116 may generally have topmost surfaces that are at the same elevation as the top surface of the seal ring 122, thereby allowing the wafer to be supported across its diameter by the LCA features 116 so that when a vacuum is drawn on the backside of the wafer via the vacuum ports 120, the wafer is clamped against the seal ring 122 and the LCA features 116 without significant bowing/cupping. It will be understood that other patterns of LCA features 116 may be used as well, depending on the needs of a particular processing regime.

In other implementations, however, the wafer support 110 may omit the vacuum ports 120, LCA features 116, and/or seal ring 122. For example, the wafer support 110 may instead have no ability to clamp the wafer in place at all or may feature electrostatic clamping features that allow the wafer support 110 to be used as an electrostatic chuck (ESC). For example, one or more electrodes may be embedded within the material of the wafer support 110 and provided with a direct current electrical potential that may electrostatically draw the wafer against the top side 124 of the wafer support 110.

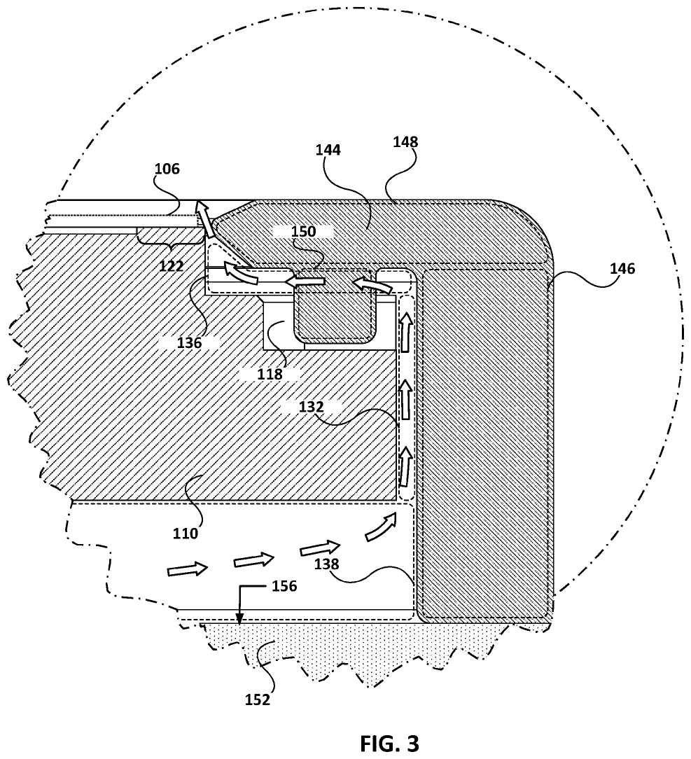

The understructure 152, in this example, includes an annular portion 154 and a tubular portion 158, the upper end of which may be proximate to the annular portion 154. The annular portion 154 may generally radiate radially outward from the tubular portion 158, e.g., in the manner of a large-diameter flange. The annular portion 154 may extend out to, and contact from beneath, the ring structure 144, thereby supporting the ring structure 144. FIG. 3 shows a detail view of the corresponding region of FIG. 1 in which the ring structure 144, as well as adjacent structures, can be seen. The ring structure 144, as shown in FIG. 3, has a circumferential wall portion 146, e.g., a generally short, large-diameter thick-walled tube, that connects with a flange portion 148 that radiates radially inward from the circumferential wall portion 146. Also visible in the cross-section of FIG. 3 (and in FIG. 1) is indexing post or feature 150, which is a cylindrical feature that protrudes from the underside of the flange portion 148. The indexing post or feature 150 is relatively small, e.g., occupying only a degree or two of arc about the circumference of the ring structure 144, and is intended to engage with corresponding radial slots 118 in the wafer support 110. A plurality, e.g., three, of indexing posts or features 150 may be included on the ring structure 144 to allow the location of the ring structure 144 relative to the wafer support 110 to be constrained. For example, the radial slots 118 may be sized just slightly larger than the indexing posts or features 150 such that the indexing posts or features 150 are able to translate radially within the radial slots 118 but are not able to translate tangentially (aside from by the small difference in size between the width of the radial slots 118 and the size of the indexing posts or features 150 in that same direction). Such an arrangement may be used to guide the ring structure 144 such that it is centered on the center axis 128 of the pedestal assembly 108 (and the wafer support 110).

In some implementations, the indexing posts or features 150 may be of sufficient vertical height (or the radial slots 118 may be of sufficient vertical depth) that the bottoms of the indexing posts or features 150 may contact the bottoms of the radial slots 118, thereby allowing the ring structure 144 to rest on, and be supported by, the wafer support 110. In other implementations, such as that pictured in FIG. 3, the ring structure 144 may not be supported by the wafer support 110 and may instead rest directly on the understructure 152. For example, the bottom surface of the circumferential wall portion 146 of the ring structure may be machined, polished, lapped, etc., so as to make a contact seal with the upper surface 156 of the understructure 152, thereby preventing or at least hindering the flow of purge gas from the first plenum volume 130 through the interface between the ring structure 144 and the understructure 152.

In the depicted example, the vertical positioning of the ring structure 144 relative to the wafer support 110 (and thus of the flange portion 148 relative to a wafer 106 (shown as a dotted outline in FIG. 3) is controlled by the vertical positioning of the understructure 152, which supports the ring structure, relative to the wafer support 110. A plurality, e.g., three or more, bosses 160 may be provided so as to protrude up from the annular portion 154 of the understructure 152 (or protrude down from the bottom side 126 of the wafer support 110) so as to provide a positive stop that limits the potential upward movement of the understructure 152 relative to the wafer support 110, thereby providing features that serve to vertically locate the understructure 152 relative to the wafer support 110. In the depicted example, the understructure 152 (or, more correctly, the bosses 160 that are part of the understructure 152 in this example) is compressed against the bottom side 126 of the wafer support 110 by a compressive force provided by a first compliant seal 164 (discussed later). Such an arrangement may serve to vertically position the ring structure 144 and the understructure 152 relative to the wafer support 110, thereby forming the first radial sub-volume 136 and the second radial sub-volume 138, while still allowing for radial translational motion between all three structures, which may accommodate potential mismatches in thermal expansion rates between materials used in such structures.

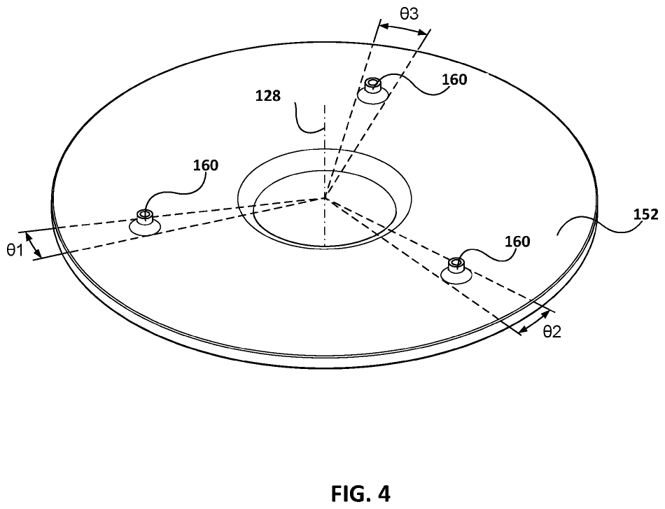

As alluded to earlier, features such as the bosses 160 may be designed, in some implementations, to occupy less than a total of 20°, 30°, or 40° of arc. FIG. 4 shows a perspective view of the example understructure 152 in isolation. The center axis 128 of the pedestal assembly 108 is shown, as are the bosses 160. As can be seen, each of the three bosses 160 occludes (or partially occludes) an angular zone that spans an angle of arc of θ₁, θ₂, or θ₃, respectively. The sum of θ₁, θ₂, and θ₃ would, in implementations such as those discussed above, be less than 20°, 30°, or 40° of arc.

The bosses 160, in this example, also serve as conduits through which lift pins may be inserted in order to reach the underside of the wafer 106 supported by the wafer support 110. For example, the wafer support 110 may have lift pin holes 112 that have corresponding counterpart lift pin holes 112 that extend through the bosses 160 and the annular portion 154 of the understructure 152. The lift pin holes 112 may be sized larger than the diameter of lift pins used with the pedestal assembly, thereby allowing the lift pins to extend through the understructure 152 and the wafer support 110 to reach the wafer 106. In such cases, top or contact surfaces of the bosses 160 (and the surface(s) on the bottom side 126 of the wafer support 110 that may contact the bosses 160) may also be machined, polished, lapped, etc. flat in order to form a contact seal between the bosses 160 and the bottom side 126 of the wafer support 110 so as to prevent or reduce the chance of purge gas leaking out of the first plenum volume 130 via the lift pin holes 112. In implementations where the bosses 160 protrude out of the bottom side 126 of the wafer support 110 instead, the bottom surfaces of the bosses 160 and the upper surface 156 of the understructure 152 may be machined, polished, lapped, etc., instead in order to form the contact seal.

In the depicted example, the first plenum volume 130 also includes a second axial sub-volume 134 that serves to extend the flow path length through the first plenum volume 130 even further than is provided by the first radial sub-volume 136, the first axial sub-volume 132, and the second radial sub-volume 138. This provides additional flow path length that may act to further homogenize the circumferential pressure and flow rate of the purge gas as it exits the first plenum volume 130, e.g., near the edge of the wafer 106.

As noted above, the understructure 152 in this example is compressed against the bottom side 126 of the wafer support 110 by the first compliant seal 164. The first compliant seal 164 may, for example, be a metal bellows seal that is compressed between the understructure 152 (e.g., the tubular portion 158 thereof) and a support collar 172. The first compliant seal 164 may thus act as both a seal and as a spring, providing a compressive force or load that may be used to press the understructure 152 into contact with the wafer support 110, e.g., with the annular portion 154. The support collar 172 may also act to support the wafer support 110, e.g., via stem 114. The stem 114 may, for example, be connected with—or even be a unitary part of—the wafer support 110. As shown, the stem 114 is a separate component that is bonded, e.g., via diffusion bonding, with the wafer support 110 and serves to structurally support the wafer support 110. It will be understood that the first compliant seal 164 may, more generally speaking, be in a load path that includes the tubular portion and that spans between the support collar 172 and the annular portion 154 of the understructure 152 and may be configured to exert a compressive load on the annular portion 154 of the understructure 152 to press the understructure 152 into contact with the wafer support 110. The first compliant seal 164 may, for example, be located as shown, but may alternatively be interposed between the tubular portion 158 of the understructure 152 and the annular portion 154 of the understructure 152.

The depicted pedestal assembly 108 also includes a tubular element 162 that is radially interposed between the tubular portion 158 of the understructure 152 and the stem 114. Thus, the second axial sub-volume 134 is partially bounded by the interior surface of the tubular portion 158 of the understructure 152 and the exterior surface of the tubular element 162. The tubular element 162 may also have an interior surface that partially bounds a second plenum volume 140. The second plenum volume 140 may also be partially bounded by the outer surface of the stem 114, and may fluidically connect the vacuum ports 120 with one or more vacuum outlets 168 (in this example, a single vacuum outlet 168 is shown, but more could be used) in the support collar 172. The tubular element 162 may be arranged such that it is compressed against the bottom side 126 of the wafer support 110 by a second compliant seal 166 (which may be similar in nature to the first compliant seal 164) that exerts a compressive load on the tubular element 162. It will be recognized that the first compliant seal 164 and the second compliant seal 166 may be placed in other positions as well. For example, the second compliant seal 166 may alternatively be interposed between the tubular element 162 and the bottom side 126 of the wafer support 110. Similarly, if the annular portion 154 and the tubular portion 158 of the understructure 152 were instead two separate pieces, the first compliant seal 164 may alternatively be interposed between the annular portion 154 and the tubular portion 158 (with the tubular portion 158 being connected with, or an extension of, the support collar 172 so as to form a sealed interface). It will be understood that the second compliant seal 166 may, more generally speaking, be in a load path that includes the tubular element 162 and that also spans between the support collar 172 and the annular portion 154 of the understructure 152 and may be configured to exert a compressive load on the tubular element 162 to press the tubular element 162 into contact with the wafer support 110.

In implementations of the pedestal assembly in which vacuum clamping or chucking functionality is not used, the vacuum ports 120, the vacuum outlet 168, and the tubular element 162 may be omitted, if desired. In such implementations, the second axial sub-volume 134 of the first plenum volume 130 may, if present, be partially bounded by the inner surface of the tubular portion 158 of the understructure 152 and the outer surface of the stem 114 instead.

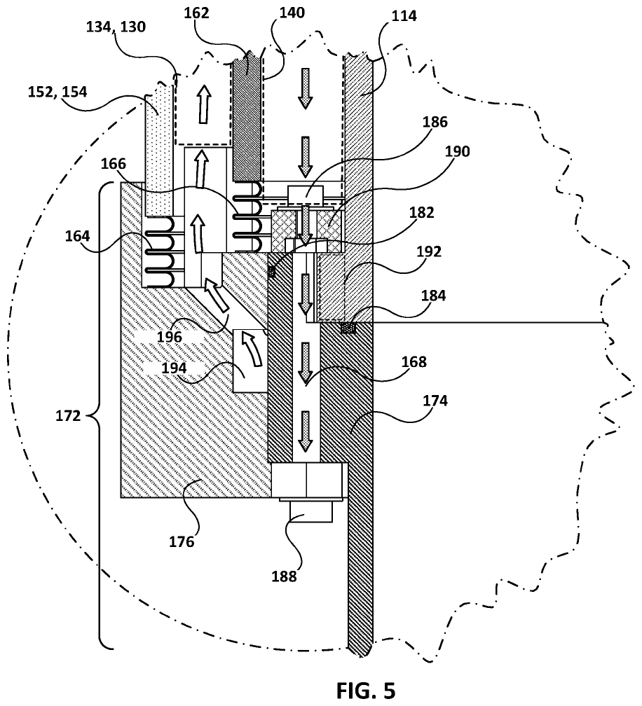

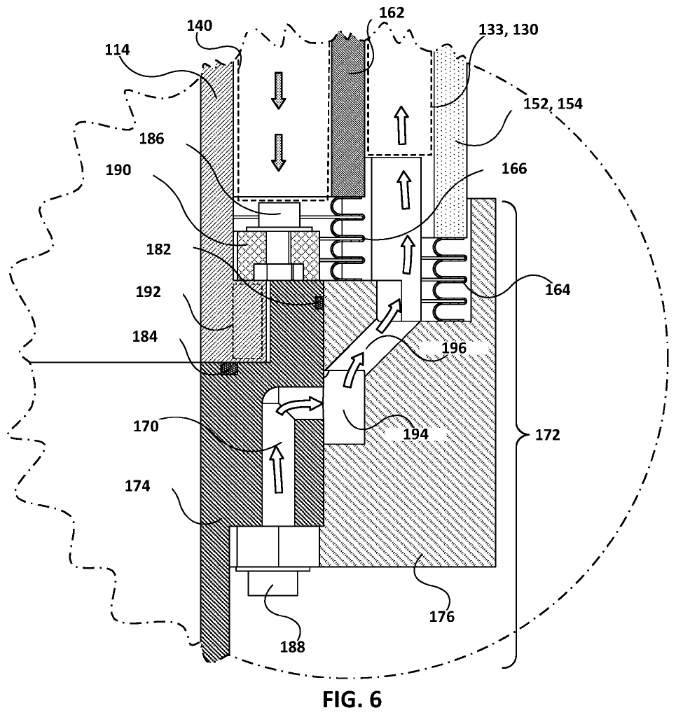

FIGS. 5 and 6 depict detail views of portions of the support collar 172. As can be seen in FIGS. 5 and 6, the support collar 172 is composed of two separate parts—a first part 174 and a second part 176 that are held together by first fasteners 188—in order to allow for various internal cavity features in the support collar 172 to be machined. In such a multi-part implementation, the support collar may also include one or more first O-ring seals 182 that may be used to seal between such parts, e.g., in locations that may be subject to a pressure differential that arises between the vacuum environment of the second plenum volume 140 and the purge gas environment in the first plenum volume 130.

The depicted support collar 172 includes an annular plenum 194 that is fluidically connected with a plurality of sloped passages 196 that, in turn, are fluidically connected with the first plenum volume 130. The annular plenum 194 and the sloped passages 196 would both be difficult or impossible to machine were the depicted support collar 172 to be machined as a single part, but are relatively straightforward to machine in a multipart assembly. However, it will be understood that the support collar 172 may also be a unitary part, e.g., a part that is cast (e.g., using investment casting) or that is additively manufactured, e.g., using direct metal laser sintering, in which case such internal features may still be utilized without requiring a multi-component approach. In other implementations, the features that are used to fluidically connect the first plenum volume 130 with a purge gas source and, if present, the second plenum volume 140 with a vacuum pump or source may be implemented differently from the example support collar 172.

In the depicted support collar 172, the vacuum outlet 168 is a straight, vertical hole through the support collar 172 that fluidically connects with the second plenum volume 140. As can be seen in FIG. 5, the vacuum outlet 168 exits the top end of the support collar 172 at a location that is covered by a clamp 190 that is compressed against the support collar 172 by second fasteners 186. The clamp 190, which may be used to clamp the stem 114 to the support collar 172, is actually a multi-piece clamp, e.g., two C-shaped components, that has an annular recess in the underside thereof. The annular recess allows for gas flow (indicated by gray arrows) from the second plenum volume 140 to the vacuum outlet 168. The clamp 190 may, for example, apply a compressive load on a shoulder 192 of the stem 114 in order to clamp it to the support collar 172. One or more second O-rings 184 may be interposed between the stem 114 and the support collar 172 in order to provide a gas-tight seal between the second plenum volume 140 and the interior of the stem 114, if desired.

As shown in FIG. 6, the support collar 172 may also include one or more purge inlets 170. Each purge inlet 170 may provide a fluidic connection between a purge gas source, e.g., a gas line leading to a fitting that supplies a purge gas, and features within the support collar 172, e.g., the annular plenum 194 and the sloped passages 196, that may be used to flow the purge gas (represented by white arrows) to the first plenum volume 130 and then towards the wafer edge.

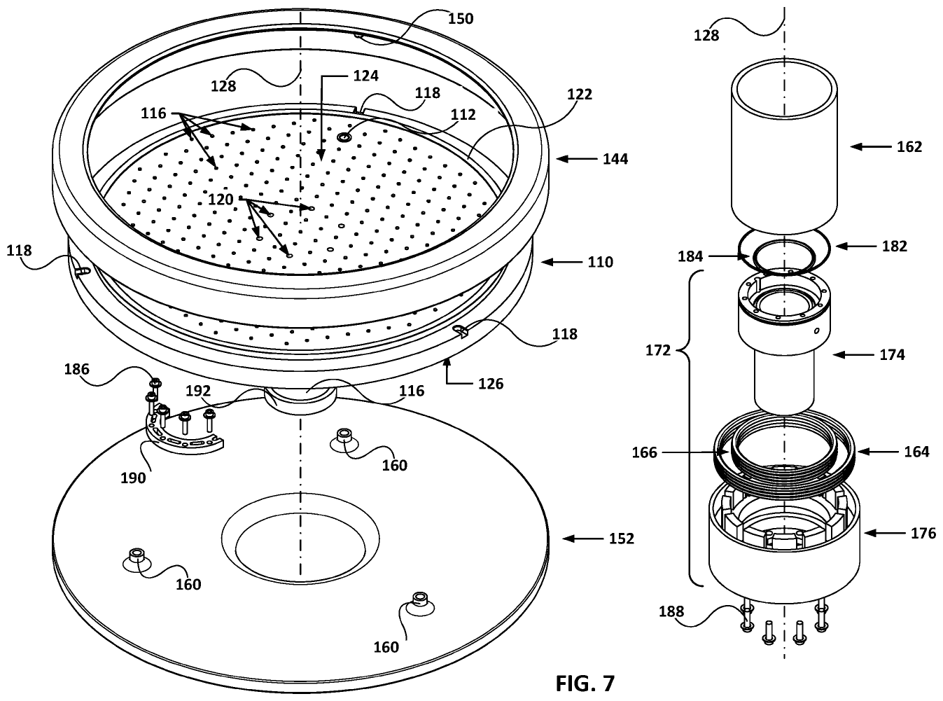

FIG. 7 depicts the example pedestal assembly of FIG. 1 in an exploded view. The radial slots 118 are more visible here, as are the LCA features 116, the vacuum ports 120, the lift pin holes 112, and the clamps 190. During assembly, the second O-ring 184 may be placed into a circular groove in the first part 174 of the support collar 172. The stem 114 may then be inserted into the first part 174 of the support collar 172 such that the shoulder 192 of the stem 114 contacts the second O-ring 184. The clamps 190 may then be placed around the stem 114 so as to contact both the shoulder 192 of the stem 114 and also the first part 174 of the support collar 172. The second fasteners 186 may then be inserted into holes in the clamps 190 and threaded into corresponding threaded holes in the first part 174 of the support collar 172. At this point, the first part 174 of the support collar may be fixedly connected with the stem 114. The stem 114, if not already attached to the wafer support 110, may then be connected with the wafer support 110.

Separately, the second part 176 of the support collar 172 may be prepared by installing the first compliant seal 164 and the second compliant seal 166 into corresponding circular seats or grooves in the second part 176. The tubular element 162 may then be placed in the same groove or seat that houses the second compliant seal 166 so as to rest on the second compliant seal, and the tubular portion 158 of the understructure 152 may similarly be placed in the same groove or seat that houses the first compliant seal 164 so as to rest on the first compliant seal 164.

The first part 174 of the support collar 172, with the attached stem 114 and wafer support 110, may then be inserted through the tubular element 162 and into the second part 176 of the support collar 172 until the first part 174 bottoms out against the second part 176 and the tubular element 162 and the understructure 152 are compressed against the bottom side 126 of the wafer support 110 by the compression of the first compliant seal 164 and the second compliant seal 166. At this point, the first fasteners 188 may be inserted through holes in the second part 176 and threaded into corresponding threaded holes in the first part 174, thereby clamping the first part 174 and the second part 176 together and forming the assembled support collar 172. The ring structure 144 may then be placed over the wafer support 110 so as to rest on the understructure 152. During such assembly, of course, the indexing features, e.g., posts, 150 may be lined up with the radial slots 118 and the lift pin holes 112 in the wafer support 110 may be lined up with the corresponding lift pin holes 112 in the understructure 152.

It will be understood, of course, that the above assembly process may be modified as needed depending on the particular designs of the components used. For example, if a unitary support collar 172 is used, the clamps 190 may have threaded studs that extend through the support collar 172 such that nuts may be threaded onto the exposed ends thereof, thereby allowing the clamp 190 to be tightened even when access to the clamp 190 is blocked by the presence of the tubular element 162 and/or the understructure 152.

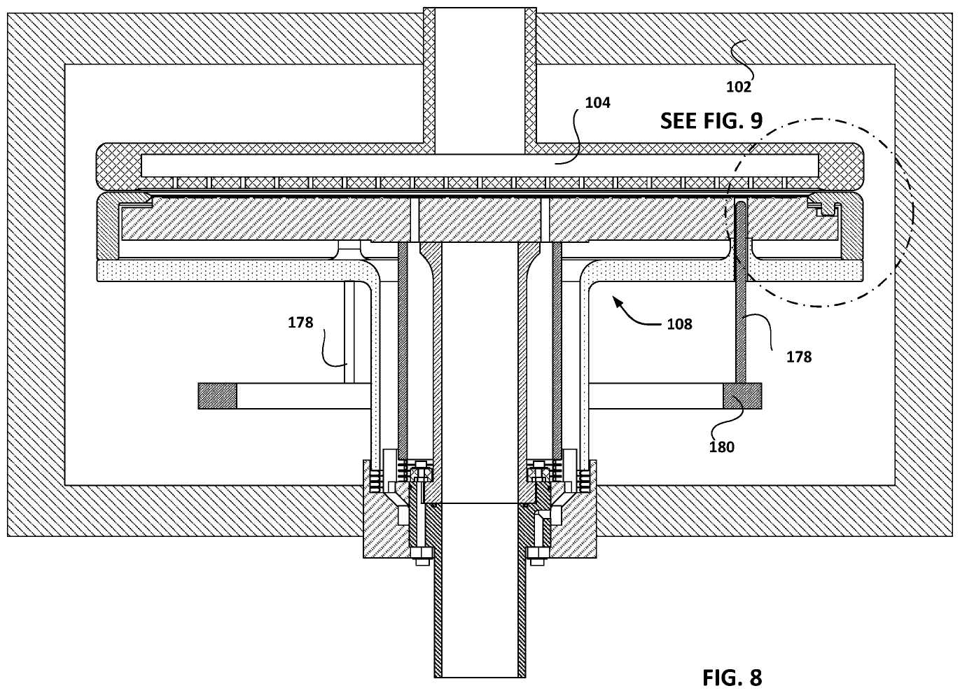

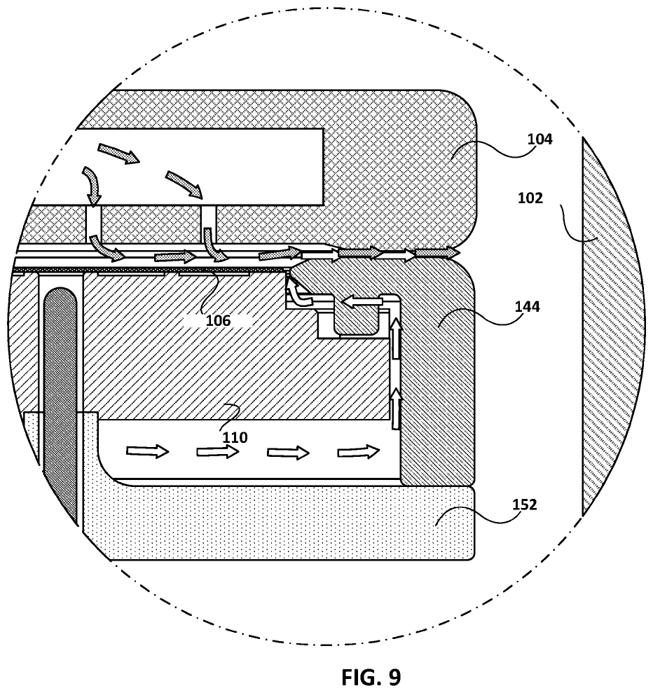

FIG. 8 depicts a cross-sectional view of the pedestal assembly of FIGS. 1 through 7 in the context of a semiconductor processing chamber. FIG. 9 depicts a detail view of the circled portion of FIG. 8.

As shown in FIGS. 8 and 9, the example pedestal assembly 108 discussed herein may be housed (at least partially) within a chamber 102 that may be part of a semiconductor processing tool, e.g., a system housing multiple processing chambers or having a processing chamber capable of housing multiple wafers simultaneously for processing operations.

The chamber 102 may also house, at least partially, a showerhead 104. The showerhead 104 may be positioned so as to be centered above the pedestal assembly 108 and may have a plurality of gas distribution ports distributed across its underside, e.g., similar to how the LCA features 116 are distributed across the top side 124 of the wafer support 110. The gas distribution ports may be provided processing gas or gases via one or more plenums internal to the showerhead 104 that may then be flowed into the space in between the showerhead 104 and the pedestal assembly 108. The wafer 106, which may be supported on the wafer support 110 of the pedestal assembly 108, may thus be exposed to the processing gas(es) in order to perform one or more processing operations.

The chamber 102 may also include a plurality of lift pins 178 that may, for example, be supported on a lift pin collar 180. The lift pin collar 180 may, in some cases, be fixedly mounted with respect to the chamber 102—in such cases, the pedestal assembly 108 may be configured to be able to be moved up and down vertically relative to the chamber 102, e.g., using a translational drive mechanism that is configured to drive the pedestal assembly 108 in such a manner. In other cases, the lift pin collar 180 may be connected with one or more vertical actuators that may be used to drive the lift pins 178 up and down vertically relative to the chamber 102 (and the pedestal assembly 108). In yet other implementations, both the lift pin collar 180 and the pedestal assembly 108 may be connected with separate vertical translation systems that allow either component or assembly to be vertical moved independently of the other. Such systems may allow the wafer 106 to be lifted off of the wafer support 110 by moving the lift pins 178 vertically relative to the wafer support 110. The showerhead 104, it will be understood, may also be configured to be vertically movable (or the pedestal assembly 108 may be understood to be movable relative to the showerhead 104) to allow the gap between the showerhead 104 and the pedestal assembly 108 to be increased to facilitate lifting the wafer 106 off of the wafer support 110 using the lift pins 178.

As can be seen in FIG. 9, process gas (indicated by grey arrows) that is delivered from the showerhead 104 may enter a relative small, confined space that is formed between the underside of the showerhead 104 and the top side 124 of the wafer support (more correctly, between the showerhead 104 and the wafer 106 supported by the wafer support 110). This confined space, which may be referred to as a microvolume, reduces the amount of volume that needs to be filled with process gas in order to expose a wafer to the process gas, reduces the amount of time it takes to purge such a volume, and provides a micro-environment that allows for multiple wafers to be processed within a common chamber using different processes.

At the same time as the process gas is being flowed, purge gas (indicated by white arrows) may be flowed through the pedestal assembly, e.g., via the first plenum volume, and flowed proximate to the wafer edge about the circumference of the wafer.

In some instances, pedestal assemblies such as those discussed herein may be equipped with heating systems embedded within the wafer support, or may be exposed to other sources of heat, that may result in the wafer support reaching temperatures of several hundred degrees Celsius, e.g., 500° C. or more, 600° C. or more, or 700° C. or more. In such cases, one or more of the ring structure, the understructure, the wafer support, the stem, the tubular element, and various other components may be made from materials that are able to withstand such high temperatures as well as the chemical environment within the processing chamber. For example, the ring structure, the understructure, the wafer support, the stem, and the tubular element may each be made of a ceramic material, such as aluminum oxide (alumina), aluminum nitride, or other similar ceramic material. In some instances, such components may be made of different types of such materials, e.g., the understructure may be aluminum oxide, while the wafer support and/or ring structure may be made of aluminum nitride. In such cases, it may be desirable to have floating or non-anchored connections between such components, such as in the example above in which the ring structure simply rests on the understructure, so as to accommodate different amounts of thermal expansion when in such components when transitioning between room temperature and such elevated temperatures.

The control of pedestal assemblies such as are described herein may be facilitated through the use of a controller that may be included as part of a semiconductor processing tool having the pedestal assembly. The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the systems disclosed herein, including operation of the various valves that may control the flow of purge gas and/or the evacuation of gas so as to draw a vacuum, operation of heater elements within a pedestal assembly, the operation of various valves that may control the flow of process gases, the operation of vertical lift mechanisms for moving pedestal assemblies and/or showerheads and/or lift pins up and down, the operation of electrostatic chucks or clamping electrodes, or various other components that may be included in, or provided in association with, pedestal assemblies as described herein.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular operation using a pedestal assembly as described herein.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber, e.g., a VTM, in communication with one or more integrated circuits located remotely (such as at the platform level or as part of a remote computer) that combine to control a purge gas flow operations to a pedestal assembly as described herein.

Without limitation, pedestal assemblies as described herein may be connected with one or more other pieces of equipment, including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, or any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item>of the one or more <items>,” “each <item>of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a pedestal assembly that includes a wafer support with a bottom side and an opposing top side that is configured to support a wafer of diameter D during semiconductor processing operations such that the wafer is centered on a center axis of the pedestal assembly, wherein:
the pedestal assembly has a first plenum volume that is substantially axially symmetric about the center axis of the pedestal assembly,
the first plenum volume includes a first axial sub-volume, a first radial sub-volume, and a second radial sub-volume,
the first axial sub-volume fluidically connects, and is fluidically interposed between, the first radial sub-volume and the second radial sub-volume,
the first radial sub-volume and the second radial sub-volume both extend radially inwards toward the center axis from the first axial sub-volume,
the first radial sub-volume extends radially inward to a location outside of a cylindrical zone of diameter D centered on the center axis,
the second radial sub-volume extends radially inward to a location inside of the cylindrical zone of diameter D centered on the center axis, and
the second radial sub-volume is further from the top side of the wafer support than the first radial sub-volume.

2. The apparatus of claim 1, further comprising a purge inlet that is fluidically connected with the first plenum volume within the pedestal assembly, wherein the first plenum volume is configured such that when a gas is flowed into the pedestal assembly via the purge inlet, the gas flows radially outward, relative to the center axis, from the second radial sub-volume to the first axial sub-volume and then flows from the first axial sub-volume to the first radial sub-volume before exiting the pedestal assembly via the first radial sub-volume.

3. The apparatus of claim 1, wherein the second radial sub-volume is free of obstructions about at least 320° of arc, in total, about the center axis.

4. The apparatus of claim 1, wherein the pedestal assembly further includes:
a ring structure having a circumferential wall portion and a flange portion extending radially inward from the circumferential wall portion to a nominally circular opening with a diameter larger than D; and
an understructure having an annular portion with an upper surface that faces towards, and is spaced apart from, the bottom side of the wafer support, wherein:
the first axial sub-volume is radially interposed between the circumferential wall portion and an outermost surface of the wafer support,
the first radial sub-volume is interposed between the flange portion and the wafer support, and
the second radial sub-volume is interposed between the understructure and the wafer support.

5. The apparatus of claim 4, wherein the understructure includes a plurality of bosses that extend from the upper surface of the understructure and contact the bottom side of the wafer support.

6. The apparatus of claim 5, wherein the bosses occupy less than 40° of arc about the center axis in total.

7. The apparatus of claim 5, wherein:
each boss has a corresponding lift pin hole therethrough,
each boss has a contact surface that contacts the wafer support, and
the contact surface of each boss and a portion of the wafer support that contacts that boss at the contact surface thereof are both flat.

8. The apparatus of claim 4, wherein:
the first plenum volume further includes a second axial sub-volume,
the second radial sub-volume is fluidically interposed between the first axial sub-volume and the second axial sub-volume,
the understructure further includes a tubular portion that has an upper end that is proximate the annular portion,
the tubular portion supports the annular portion, and
the second axial sub-volume is bounded, at least in part, by an interior surface of the tubular portion.

9. The apparatus of claim 8, further comprising a first compliant seal element and a support collar, wherein:
the first compliant seal element is in a load path that includes the tubular portion and spans between the support collar and the annular portion of the understructure, and
the first compliant seal element exerts a compressive load on the annular portion of the understructure, thereby pressing it into contact with the wafer support.

10. The apparatus of claim 9, wherein:
the first plenum volume further includes a second axial sub-volume, and
the second radial sub-volume is fluidically interposed between the first axial sub-volume and the second axial sub-volume.

11. The apparatus of claim 8, wherein:
the pedestal assembly further includes a second plenum volume, one or more vacuum outlets, and one or more vacuum ports,
the second plenum volume is fluidically isolated from the first plenum volume within the pedestal assembly,
the one or more vacuum ports lead from the bottom side of the wafer support to the top side of the wafer support, and
the second plenum volume fluidically connects, and is fluidically interposed between, the one or more vacuum ports and the one or more vacuum outlets.

12. The apparatus of claim 11, further comprising a tubular element, wherein:
the second plenum volume is bounded, in part, by the tubular element.

13. The apparatus of claim 12, further comprising a stem, wherein:
the stem supports the wafer support,
the tubular element encircles the stem, and
the second plenum volume is further bounded, at least in part, by the stem.

14. The apparatus of claim 12, further comprising a first compliant seal element, a second compliant seal element, and a support collar, wherein:
the first compliant seal element is in a first load path that includes the tubular portion and spans between the support collar and the annular portion of the understructure,
the second compliant seal element is in a second load path that includes the tubular element and also spans between the support collar and the annular portion of the understructure,
the first compliant seal element exerts a compressive load on the annular portion of the understructure, thereby pressing it into contact with the wafer support, and
the second compliant seal element is arranged to cause a compressive load to be exerted on the annular portion of the understructure, thereby also pressing it into contact with the wafer support.

15. The apparatus of claim 4, wherein the ring structure, the understructure, and the wafer support are all made of ceramic materials.

16. The apparatus of claim 15, wherein the ring structure is made of aluminum nitride and the understructure is made of aluminum oxide.

17. The apparatus of claim 1, wherein:
the wafer support further includes a plurality of low-contact-area (LCA) features distributed across a portion of the top side of the wafer support, and
each LCA feature is a protrusion from a recessed portion of the top side of the wafer support.

18. The apparatus of claim 1, further comprising a showerhead configured to direct one or more processing gases, when the one or more processing gases are flowed into the showerhead, towards the top side of the wafer support.

19. The apparatus of claim 18, further comprising a semiconductor processing chamber, wherein the wafer support is located within the semiconductor processing chamber.
